(19) United States
(12) Patent Application Publication
(10) Pub. No.: US 2026/0231771 A1
(43) Pub. Date: Aug. 6, 2026

(54) Semiconductor Device and Method of Making IPD Structure on Glass Substrate

(71) Applicant: STATS ChipPAC Management Pte. Ltd., Singapore (SG)

(72) Inventors: SeungMan Hong, Incheon (KR); YongTaek Lee, Seoul (KR); OhYoung Kwon, Seoul (KR); SoJeong Bae, Incheon (KR)

(73) Assignee: STATS ChipPAC Management Pte. Ltd., Singapore (SG)

(21) Appl. No.: 19/047,268

(22) Filed: Feb. 6, 2025

(51) Int. Cl. H01L 23/58; H01L 23/00; H01L 23/15

(52) U.S. Cl. CPC H10W 42/00; H10W 70/692; H10W 72/244; H10W 72/533

(57) ABSTRACT

A semiconductor device has semiconductor substrate. An integrated passive device (IPD) structure is formed over the semiconductor substrate. The semiconductor substrate and IPD structure are disposed over a glass substrate. The semiconductor substrate, IPD structure, and glass substrate are disposed over a printed circuit board (PCB).

### FIELD OF THE INVENTION

The present invention relates in general to semiconductor devices and, more particularly, to semiconductor devices and methods of making integrated passive device (IPD) structures on glass substrates.

### BACKGROUND OF THE INVENTION

Semiconductor devices are commonly found in modern electronic products. Semiconductor devices perform a wide range of functions such as signal processing, high-speed calculations, transmitting and receiving electromagnetic signals, controlling electronic devices, transforming sunlight to electricity, and creating visual images for television displays. Semiconductor devices are found in the fields of communications, power conversion, networks, computers, entertainment, and consumer products. Semiconductor devices are also found in military applications, aviation, automotive, industrial controllers, and office equipment.

Integrated passive devices (IPDs) are electronic components where resistors, capacitors, inductors, microstriplines, impedance matching elements, baluns, other similar elements, or combinations thereof are integrated in the same package or on the same substrate. Integrated passive devices can be packaged, bare dies/chips or even stacked with active integrated circuits, or other IPDs in an electronic system assembly.

The substrate for IPDs can be formed of any suitable rigid material, e.g., ceramic, glass, or silicon. Traditional silicon substrates have a high dielectric constant (Dk) and loss tangent (Df), resulting in signal loss. Glass substrates improve electrical performance but create issues with the IPD device layers having low adhesion and becoming separated from the substrate. Therefore, a need exists for new semiconductor devices and methods of making IPD structures with glass substrates.

### BRIEF DESCRIPTION OF THE DRAWINGS

FIGS. 1a-1c illustrate a semiconductor wafer with a plurality of semiconductor die separated by a saw street;

FIGS. 2a-2j illustrate forming an IPD structure on glass substrate;

FIGS. 3a-3b illustrate an optional backgrinding step;

FIGS. 4a-4d illustrate mounting the IPD module on a substrate or PCB of a larger electronic device;

FIGS. 5a and 5b illustrate semiconductor packages formed with the IPD modules; and

FIG. 6 illustrates an electronic device with the IPD module.

### DETAILED DESCRIPTION OF THE DRAWINGS

The present invention is described in one or more embodiments in the following description with reference to the figures, in which like numerals represent the same or similar elements. While the invention is described in terms of the best mode for achieving the invention's objectives, it will be appreciated by those skilled in the art that it is intended to cover alternatives, modifications, and equivalents as may be included within the spirit and scope of the invention as defined by the appended claims and their equivalents as supported by the following disclosure and drawings. The features shown in the figures are not necessarily drawn to scale. Elements assigned the same reference number in the figures have a similar function and description to each other. The term “semiconductor die” as used herein refers to both the singular and plural form of the words, and accordingly, can refer to both a single semiconductor device and multiple semiconductor devices.

Semiconductor devices are generally manufactured using two complex manufacturing processes: front-end manufacturing and back-end manufacturing. Front-end manufacturing involves the formation of a plurality of die on the surface of a semiconductor wafer. Each die on the wafer contains active and passive electrical components, which are electrically connected to form functional electrical circuits. Active electrical components, such as transistors and diodes, have the ability to control the flow of electrical current. Passive electrical components, such as capacitors, inductors, and resistors, create a relationship between voltage and current necessary to perform electrical circuit functions.

Back-end manufacturing refers to cutting or singulating the finished wafer into the individual semiconductor die and packaging the semiconductor die for structural support, electrical interconnect, and environmental isolation. To singulate the semiconductor die, the wafer is scored and broken along non-functional regions of the wafer called saw streets or scribes. The wafer is singulated using a laser cutting tool or saw blade. After singulation, the individual semiconductor die are disposed on a package substrate that includes pins or contact pads for interconnection with other system components. Contact pads formed over the semiconductor die are then connected to contact pads within the package. The electrical connections can be made with conductive layers, bumps, stud bumps, conductive paste, or wirebonds. An encapsulant or other molding material is deposited over the package to provide physical support and electrical isolation. The finished package is then inserted into an electrical system and the functionality of the semiconductor device is made available to the other system components.

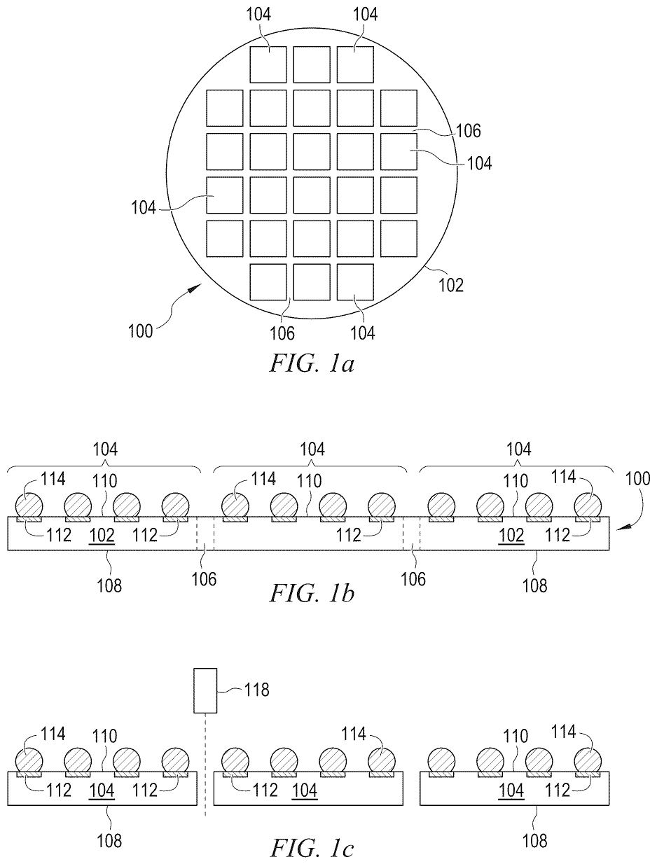

FIG. 1a shows a semiconductor wafer 100 with a base substrate material 102, such as silicon, germanium, aluminum phosphide, aluminum arsenide, gallium arsenide, gallium nitride, indium phosphide, silicon carbide, or other bulk material for structural support. A plurality of semiconductor die or components 104 is formed on wafer 100 separated by a non-active, inter-die wafer area or saw street 106. Saw street 106 provides cutting areas to singulate semiconductor wafer 100 into individual semiconductor die 104. In one embodiment, semiconductor wafer 100 has a width or diameter of 100-450 millimeters (mm).

FIG. 1b shows a cross-sectional view of a portion of semiconductor wafer 100. Each semiconductor die 104 has a back or non-active surface 108 and an active surface 110 containing analog or digital circuits implemented as active devices, passive devices, conductive layers, and dielectric layers formed within the die and electrically interconnected according to the electrical design and function of the die. For example, the circuit may include one or more transistors, diodes, and other circuit elements formed within active surface 110 to implement analog circuits or digital circuits, such as a digital signal processor (DSP), application specific integrated circuits (ASIC), memory, or other signal processing circuit. Semiconductor die 104 may also contain IPDs, such as inductors, capacitors, and resistors, for RF signal processing.

An electrically conductive layer 112 is formed over active surface 110 using physical vapor deposition (PVD), chemical vapor deposition (CVD), electrolytic plating, electroless plating, or other suitable metal deposition process. Conductive layer 112 can be one or more layers of aluminum (Al), copper (Cu), tin (Sn), nickel (Ni), gold (Au), silver (Ag), or other suitable electrically conductive material. Conductive layer 112 operates as contact pads electrically connected to the circuits on active surface 110.

An electrically conductive bump material is deposited over conductive layer 112 using an evaporation, electrolytic plating, electroless plating, ball drop, or screen printing process. The bump material can be Al, Sn, Ni, Au, Ag, lead (Pb), bismuth (Bi), Cu, solder, and combinations thereof, with an optional flux solution. For example, the bump material can be eutectic Sn/Pb, high-lead solder, or lead-free solder. The bump material is bonded to conductive layer 112 using a suitable attachment or bonding process. In one embodiment, the bump material is reflowed by heating the material above its melting point to form balls or bumps 114. In one embodiment, bump 114 is formed over an under bump metallization (UBM) having a wetting layer, barrier layer, and adhesion layer. Bump 114 can also be compression bonded or thermocompression bonded to conductive layer 112. Bump 114 represents one type of interconnect structure that can be formed over conductive layer 112. The interconnect structure can also use bond wires, conductive paste, stud bumps, micro bumps, or another type of electrical interconnect.

In FIG. 1c, semiconductor wafer 100 is singulated through saw street 106 using a saw blade or laser cutting tool 118 into individual semiconductor die 104. The individual semiconductor die 104 can be inspected and electrically tested for identification of known good die or known good unit (KGD/KGU) post singulation.

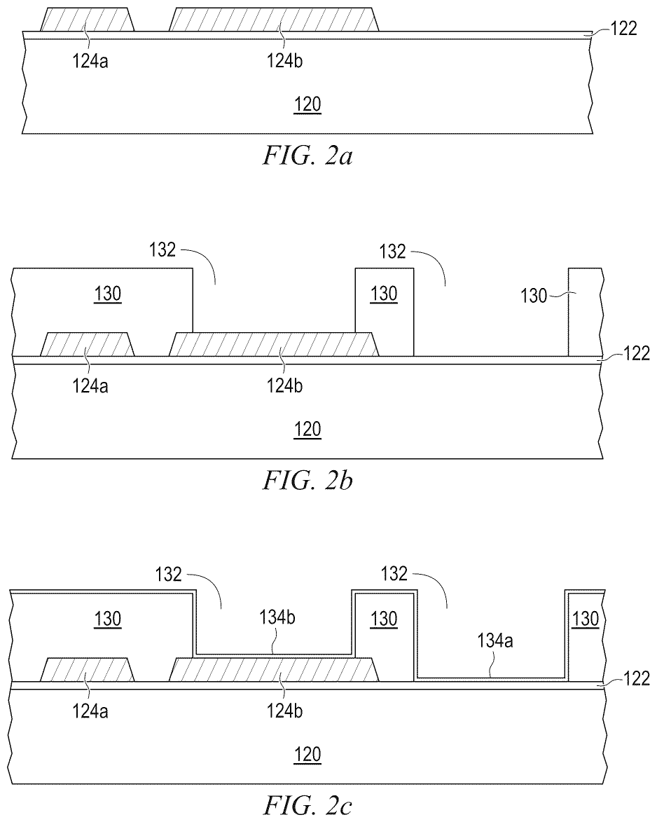

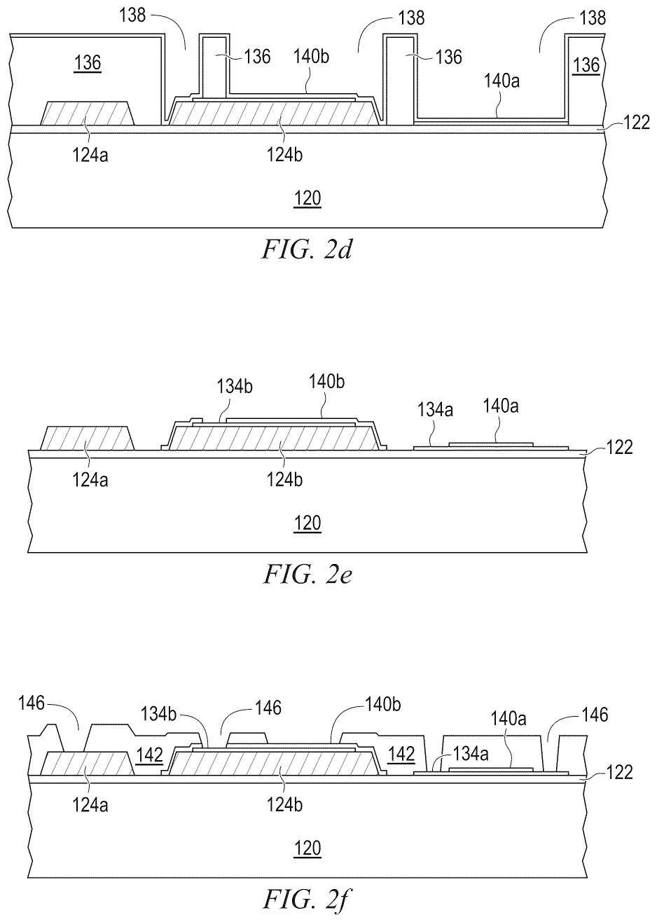

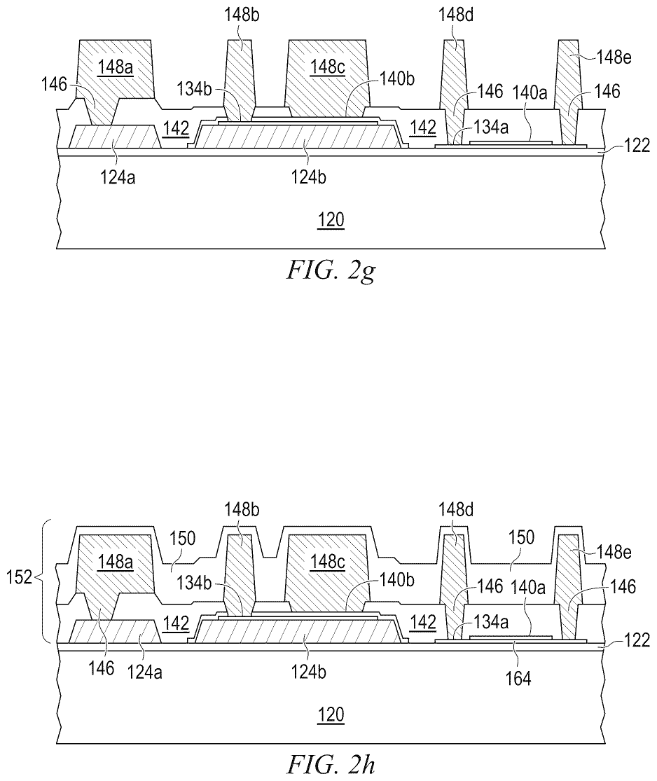

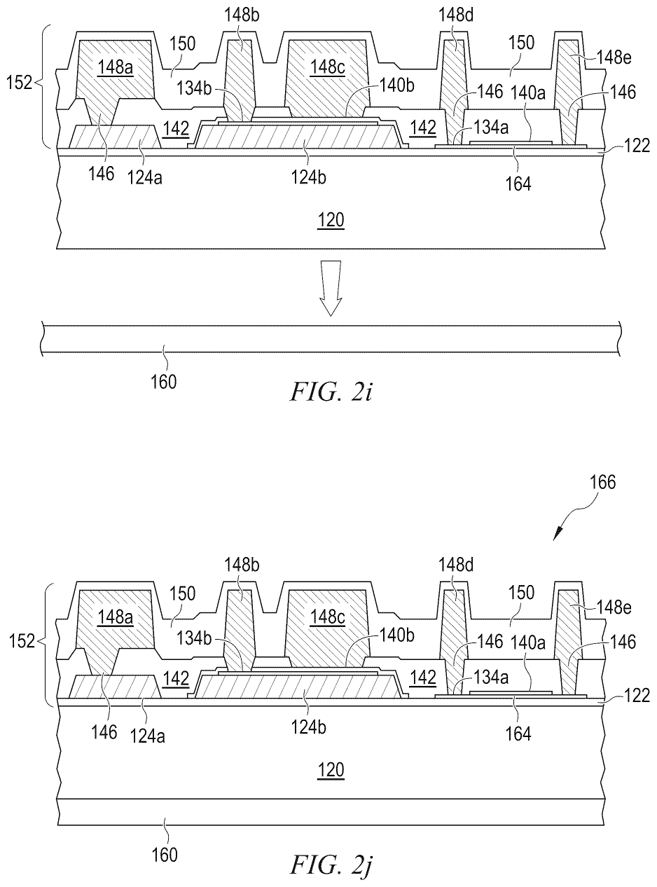

FIGS. 2a-2j illustrate forming integrated passive device (IPD) modules with glass substrates. IPDs are referred to as integrated because passive devices are formed over a substrate using common semiconductor manufacturing steps, allowing the IPDs to be integrated onto a semiconductor die with other functionality. A silicon substrate 120 is used in FIG. 2a. Substrate 120 can be the same or similar to wafer 100 in FIG. 1a. Substrate 120 may have active devices formed in the silicon material as with active surface 110 above, or the silicon material can be used only as a substrate for the overlying IPDs. Substrate 120 can also be other semiconductor material, aluminum, steel, copper, another metal, glass, polymer, or formed from any other suitable rigid material for structural support of the IPDs being formed.

An insulating layer 122 is formed over substrate 120. Insulating layer 122 contains one or more layers of silicon dioxide (SiO2), silicon nitride (Si3N4), silicon oxynitride (SiON), tantalum pentoxide (Ta2O5), aluminum oxide (Al2O3), solder resist, polyimide (PI), benzocyclobutene (BCB), polybenzoxazoles (PBO), and other material having similar insulating and structural properties. Insulating layers can be formed using PVD, CVD, printing, lamination, spin coating, spray coating, sintering, or thermal oxidation. Openings can be formed through insulating layer 122 to allow electrical connection if active circuit elements were formed in substrate 120.

A conductive layer 124 is formed over insulating layer 122. Conductive layer 124 can be one or more layers of Al, Cu, Sn, Ni, Au, Ag, or other suitable electrically conductive material. Conductive layers can be formed using PVD, CVD, electrolytic plating, electroless plating, or other suitable metal deposition process. Conductive layer 124 provides horizontal electrical interconnect across substrate 120. Portions of conductive layer 124 can be electrically common or electrically isolated depending on the design and function of the package being formed. Conductive layer 124 is deposited into optional openings of insulating layer 122 to physically and electrically connect to circuit elements in substrate 120, if formed. Conductive layer 124 is patterned using a photolithographic mask, etching after deposition, selective plating, or another suitable process.

Conductive layer 124 is formed in the same manner as a normal metal-1 (M1) layer over a semiconductor die or wafer. Portions of conductive layer 124 can be patterned to form integrated passive devices, e.g., shaped in coils to form part of inductors or as a capacitor plate. Portions of conductive layer 124 also form conductive traces across the surface of substrate 120 to act as a redistribution layer (RDL) and contact pads for contact with subsequently formed conductive layers or external devices. In particular, portion 124a in FIG. 2a is shaped to form a conductive trace with contact pads at its ends and portion 124b is shaped to form a contact pad connected to a bottom plate of a capacitor. Portions of conductive layer 124 can be shaped as desired to form any suitable circuit elements.

FIG. 2b shows a mask layer 130 formed over substrate 120. Mask layer 130 is a photolithographic mask that is formed completely covering substrate 120 and then developed to allow removal of desired portions to form openings 132. In FIG. 2c, a Tantalum-Silicon (TaSi) layer 134 is formed by depositing the appropriate materials into openings 132. TaSi layer 134 can be deposited using any of the methods discussed above for conductive layer 124. TaSi layer 134 is formed completely covering mask layer 130 and then only the portions on the bottom surfaces in openings 132 remain after removal of the mask. Openings 132 define the shape of TaSi layer 134 that is left in the final product after mask 130 is removed. In other embodiments, TaSi layer 134 is formed covering substrate 120 completely without a mask and then patterned to the desired structures or selectively formed in the desired pattern.

TaSi layer 134 is used as a layer with a controllable electrical resistance. In FIG. 2c, portion 134a is formed independently to operate as a resistor. Portion 134b is formed on conductive layer portion 124b to form part of the capacitor structure. TaSi layer 134 can be selectively formed using mask 130 with openings 132 into any desired pattern for forming any desired passive components over substrate 120.

In FIG. 2d, a second mask layer 136 is formed over substrate 120 with openings 138 formed through the mask layer. A nitride layer 140 is formed over mask 136 and into openings 138. Nitride layer 140 remains in the pattern of openings 138 after mask 136 is removed in FIG. 2e. In other embodiments, nitride layer 140 is formed covering substrate 120 completely without a mask and then patterned to the desired formations or selectively formed in the desired pattern.

Nitride layer portion 140b is an insulating layer that operates as a dielectric layer over the capacitor plate of conductive layer portion 124b. Nitride layer portion 140a provides a protective layer over the resistor formed by TaSi layer portion 134a. Nitride layer 140 can be formed in any suitable pattern to create the desired electrical components.

Insulating layer 142 is formed over substrate 120 in FIG. 2f. Openings 146 are formed through insulating layer 142 to expose underlying elements for electrical interconnect. Insulating layer 142 can be formed as discussed above for insulating layer 120 and patterned using photolithography, laser ablation, or another suitable means. Insulating layer 142 is a PI layer in one embodiment.

In FIG. 2g, a conductive layer 148 is formed over insulating layer 142, including extending into openings 146. Conductive layer 148 is formed and patterned as discussed above for conductive layer 124. Portion 148a operates as a contact pad for the conductive trace of conductive layer portion 124a. Portions 148b and 148c operate as contact pads for the underlying capacitor. Portions 148d and 148e operate as contact pads for the underlying resistor. Conductive layer 148 can be patterned into contact pads, conductive traces, and other structures to implement the desired electrical functionality.

Insulating layer 150 is formed over conductive layer 148 in FIG. 2h to complete IPD structure 152. Insulating layer 150 is formed as described above for insulating layer 142. Insulating layer 150 is a PI layer in one embodiment. Openings are formed through insulating layer 150 to expose contact pads of conductive layer 148 where needed for electrical interconnect. Conductive layers 124 and 148, nitride layer 140, TaSi layer 134, and any other layer formed of any other suitable material can be used to form any desired component as part of IPD structure 152.

FIG. 2i illustrates substrate 120 with IPD structure 152 disposed over a glass substrate 160. Glass substrate 160 is a sheet of Corning glass in one embodiment. Any other suitable material is used for glass substrate 160 in other embodiments. A thickness of glass substrate 160 can be adjusted to benefit impedance matching. Substrate 120 is disposed down onto glass substrate 160 and attached to the glass substrate using an appropriate adhesive in FIG. 2j to complete an IPD module 166. IPD structure 152 has been formed on a silicon substrate 120 and then disposed on glass substrate 160. Glass substrate 160 is directly attached to substrate 120 by an adhesive without any other intervening elements. In other embodiments, additional protective or other layers are formed on the surfaces of substrate 120, glass substrate 160, or both as interface layers between the substrates.

The attachment of glass substrate 160 completes the manufacturing process. In some embodiments, IPD structure 152, substrate 120, and glass substrate 160 are formed as a panel of units, which are singulated from each other using a laser cutting tool or saw blade to separate the units after the step shown in FIG. 2j. IPD modules 166 are then placed into a JEDEC tray or tape-and-reel for distribution or immediately used in a larger electronic device or semiconductor package.

Placing glass substrate 160 under substrate 120 enhances electrical performance and stability of IPD module 166 due to the low Dk, Df, and dissipation factor of glass. In particular, the low Df of glass substrate 160 boosts the Q-factor of inductor structures. This approach not only improves the electrical performance but also enhances the manufacturing efficiency and reliability of the semiconductor devices. By using a silicon wafer 120 to implement the interposer layer, the risk of the RDL layer detaching from glass substrate 160 is reduced.

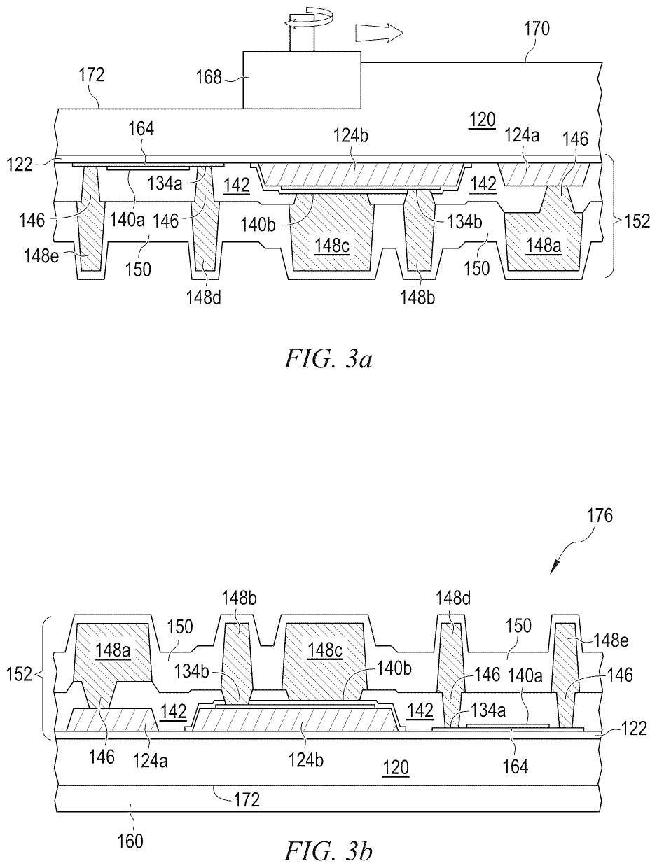

FIGS. 3a and 3b illustrate an additional optional step of backgrinding substrate 120 prior to attaching glass substrate 160. In FIG. 3a, IPD structure 152 has been completed as shown in FIG. 2 h. A grinder 168 or other suitable tool is used to reduce a thickness of substrate 120. The thickness of substrate 120 can be reduced using chemical etching, chemical-mechanical planarization, or any other suitable means. Original back surface 170 is removed and a new back surface 172 is exposed. FIG. 3b shows glass substrate 160 attached to the new back surface 172 to complete an IPD module 176. Reducing a thickness of substrate 120 brings glass substrate 160 closer to IPD structure 152, thus improving the above-mentioned benefits of the glass substrate. Df, Dk, and Q-Factor are further improved.

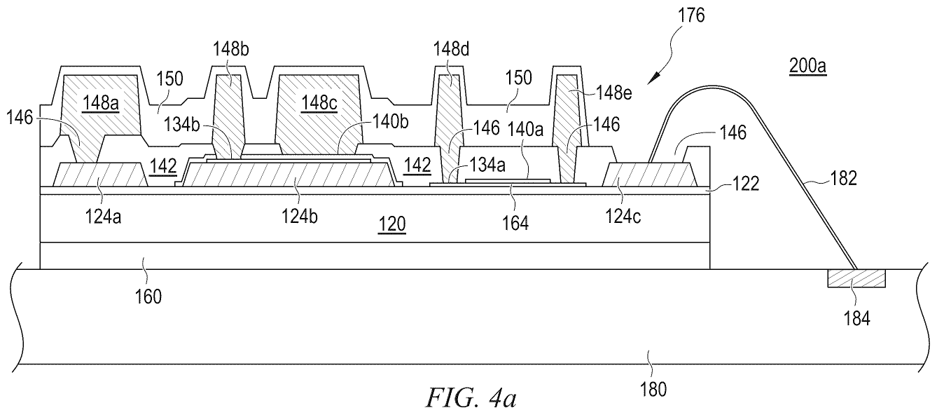

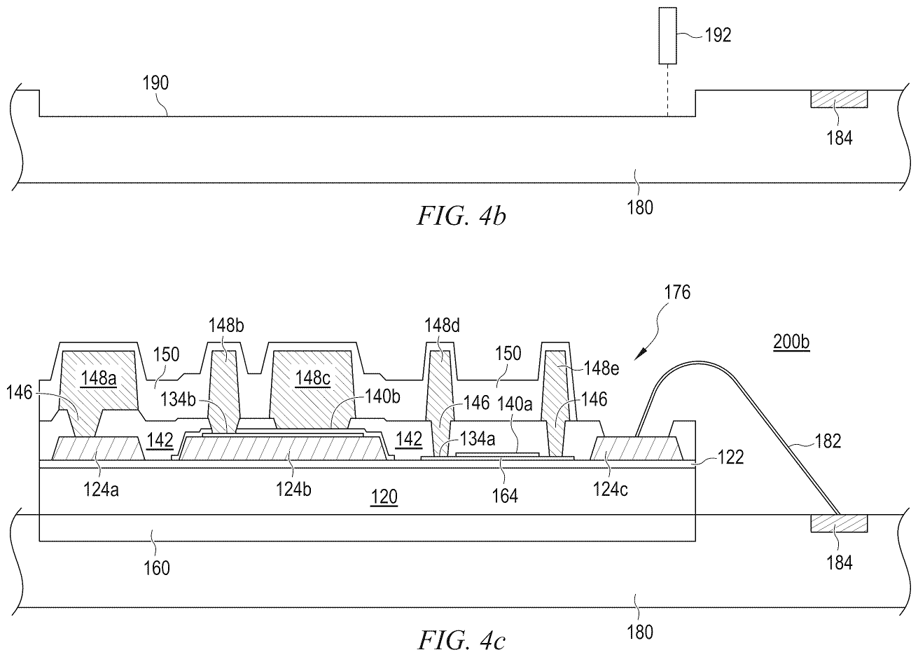

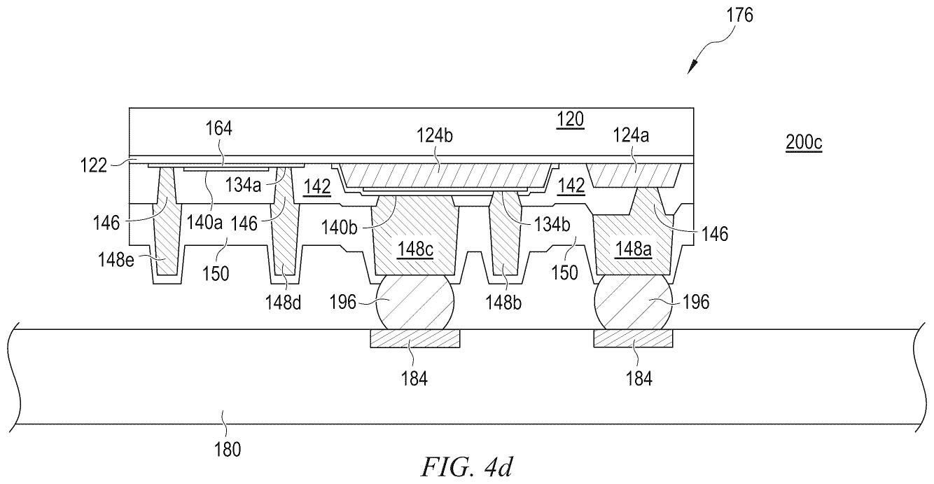

FIGS. 4a-4d show various ways of mounting IPD module 166 or 176 on a substrate 180 of a larger electronic device or semiconductor package. FIG. 4a shows IPD module 176 mounted onto a PCB 180 of an electronic device 200a. PCB 180 can also be a package substrate of a larger semiconductor package incorporating IPD module 176 together with semiconductor die 104. An adhesive layer is used to attach glass substrate 160 to PCB 180.

Conductive layer 124 has an additional contact pad 124c formed without an overlying portion of conductive layer 148. An opening 146 leaves contact pad 124c exposed for subsequent external interconnect. A bond wire 182 connects contact pad 124c of IPD module 176 to a contact pad 184 of PCB 180. Bond wire 182 is mechanically and electrically coupled to contact pads 124c and 184 by thermocompression bonding, ultrasonic bonding, wedge bonding, stitch bonding, ball bonding, or another suitable bonding technique. Bond wire 182 includes a conductive material such as Cu, Al, Au, Ag, a metal alloy, or a combination thereof. Any desired number of bond wires 182 can connect multiple contact pads 124c and multiple contact pads 184 in any desired configuration to implement the intended electrical functionality.

FIG. 4b shows optionally forming a recess 190 in substrate 180 prior to mounting IPD module 176 in the recess. Recess 190 is formed by laser ablation using a laser 192. In other embodiments, recess 190 is formed by mechanical etching, chemical etching. Recess 190 may also be formed while building up layers for PCB 180. PCB 180 is typically formed by forming a plurality of conductive and insulating layers interleaved on top of each other. Any number of the upper conductive and insulating layers can be formed with openings to leave recess 190 in the final PCB 180.

FIG. 4c shows IPD module 176 disposed with glass substrate 160 on PCB 180 in recess 190 as part of an electronic device or semiconductor package 200b. A footprint of recess 190 can be nearly identical to glass substrate 160 such that the recess is almost completely filled by the glass substrate, or the recess can have a large footprint. A depth of recess 190 can be used to customize the overall package or device height. Recess 190 can be deeper than a height of glass substrate 160, or not as deep as the glass substrate. A taller IPD structure 152 can be accommodated by further recessing IPD module 176 into substrate 180. Recess 190 provides precise height control for the package or device 200b. One or more bond wires 182 are formed to connect IPD structure 152 to contact pads 184 as described above.

FIG. 4d illustrates an alternative with electronic device or semiconductor package 200c having IPD module 176 flipchip mounted onto substrate 180. Openings are formed through insulating layer 150 to expose contact pads of conductive layer 148. Solder bumps 196 are formed on conductive layer 148 in the openings as described above for solder bumps 114.

IPD module 176 with solder bumps 196 is flipped and disposed on substrate 180 with the solder bumps aligned to contact pads 184. Solder bumps 196 are reflowed to physically and electrically couple IPD module 176 to substrate 180. Any number and layout of solder bumps 196 can be used as necessary to implement the desired electrical functionality. In some embodiments, an adhesive or underfill layer is used between IPD module 176 and PCB 180.

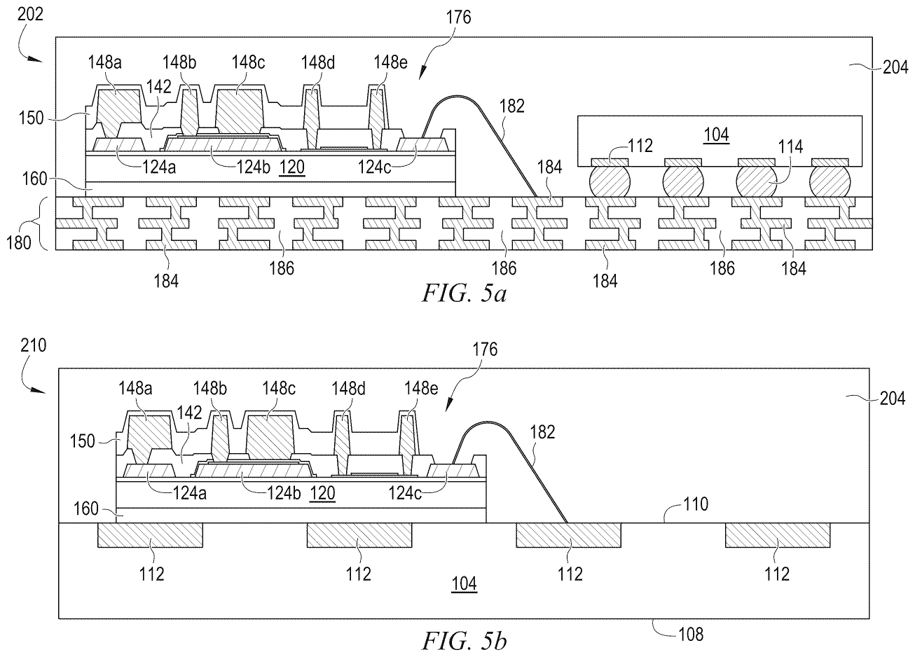

FIGS. 5a and 5b illustrate semiconductor packages formed with IPD modules 176, and semiconductor die 104. In FIG. 5a, a semiconductor package 202 has IPD module 176 disposed on substrate 180 along with semiconductor die 104. Substrate 180 is a multi-layered interconnect substrate including conductive layers 184 and insulating layers 186. Conductive layers 184 can be one or more layers of Al, Cu, Sn, Ni, Au, Ag, or other suitable electrically conductive material. Conductive layers 184 can be formed using PVD, CVD, electrolytic plating, electroless plating, or other suitable metal deposition process. Conductive layers 184 provide horizontal electrical interconnect across substrate 180 and vertical electrical interconnect between the top and bottom surfaces. Portions of conductive layers 184 can be electrically common or electrically isolated depending on the design and function of the package or module being formed.

Insulating layers 186 contain one or more layers of SiO2, Si3N4, SiON, Ta2O5, Al2O3, solder resist, PI, BCB, PBO, and other material having similar insulating and structural properties. Insulating layers 186 can be formed using PVD, CVD, printing, lamination, spin coating, spray coating, sintering, thermal oxidation, or another suitable process. Insulating layers 186 provide isolation between conductive layers 184. Any number of conductive layers 184 and insulating layers 186 can be interleaved over each other to form substrate 180.

Any other suitable type of package substrate or leadframe is used for substrate 180 in other embodiments. For example, substrate 180 can be a laminate interposer, PCB, wafer-form, strip interposer, leadframe, or another suitable substrate. Substrate 180 may include one or more laminated layers of polytetrafluoroethylene pre-impregnated (prepreg), FR-4, FR-1, CEM-1, or CEM-3 with a combination of phenolic cotton paper, epoxy, resin, woven glass, matte glass, polyester, and other reinforcement fibers or fabrics. Substrate 180 can also be a multi-layer flexible laminate, ceramic, copper clad laminate, glass, or semiconductor wafer including an active surface containing one or more transistors, diodes, and other circuit elements to implement analog circuits or digital circuits.

Semiconductor die 104 is picked and placed onto substrate 180 with bumps 114 on the substrate. Bumps 114 are reflowed to physically and electrically couple semiconductor die 104 to substrate 180. Conductive layers 184 electrically couple semiconductor die 104 to IPD module 176. An encapsulant or molding compound 204 is deposited over substrate 180, semiconductor die 104, and IPD module 176. Encapsulant 204 is deposited using a paste printing, compression molding, transfer molding, liquid encapsulant molding, vacuum lamination, spin coating, or other suitable applicator. Encapsulant 204 can be liquid or granular polymer composite material, such as epoxy resin, epoxy acrylate, or another suitable polymer, with or without a filler. Encapsulant 204 is non-conductive, provides structural support, and environmentally protects the embedded electrical components from external elements and contaminants. Additional solder bumps or another interconnect structure can be formed on substrate 180 opposite semiconductor die 104 for subsequent external interconnect to a larger system.

FIG. 5b shows a semiconductor package 210 being formed by disposing IPD module 176 directly on active surface 110 of semiconductor die 104 instead of substrate 180. Encapsulant 204 is deposited over semiconductor die 104 and IPD module 176 as described above. Conductive vias or other conductive structures can be formed through encapsulant 204 for electrical interconnection to external systems.

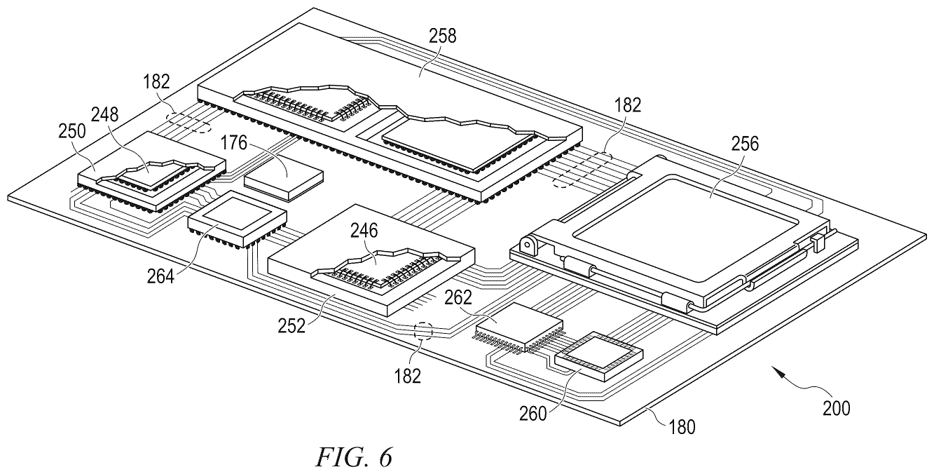

FIG. 6 illustrates an exemplary electronic device 200 incorporating one of the above-described IPD modules, e.g., IPD module 176, along with a plurality of semiconductor packages disposed on a surface of PCB 180. Electronic device 200 can have one type of semiconductor package, or multiple types of semiconductor packages, depending on the application. In other embodiments, IPD module 176 is incorporated as only one part of another larger semiconductor package, e.g., a system-in-package, before being incorporated into a larger electronic device 200.

Electronic device 200 can be a stand-alone system that uses the semiconductor packages to perform one or more electrical functions. Alternatively, electronic device 200 can be a subcomponent of a larger system. For example, electronic device 200 can be part of a tablet, cellular phone, digital camera, communication system, or other electronic device. Alternatively, electronic device 200 can be a graphics card, network interface card, or other signal processing card that can be inserted into a computer. The semiconductor package can include microprocessors, memories, ASICs, logic circuits, analog circuits, RF circuits, discrete devices, or other semiconductor die or electrical components. Miniaturization and weight reduction are essential for the products to be accepted by the market. The distance between semiconductor devices may be decreased to achieve higher density.

In FIG. 6, PCB 180 provides a general substrate for structural support and electrical interconnect of the semiconductor packages disposed on the PCB. Conductive signal traces 182 are formed over a surface or within layers of PCB 180 using evaporation, electrolytic plating, electroless plating, screen printing, or other suitable metal deposition process. Signal traces 182 provide for electrical communication between each of the semiconductor packages, mounted components, and other external system components. Traces 182 also provide power and ground connections to each of the semiconductor packages.

In some embodiments, a semiconductor device has two packaging levels. First level packaging is a technique for mechanically and electrically attaching the semiconductor die to an intermediate substrate. Second level packaging involves mechanically and electrically attaching the intermediate substrate to the PCB. In other embodiments, a semiconductor device may only have the first level packaging where the die is mechanically and electrically disposed directly on the PCB.

For the purpose of illustration, several types of first level packaging, including bond wire package 246 and flipchip 248, are shown on PCB 180. Additionally, several types of second level packaging, including ball grid array (BGA) 250, bump chip carrier (BCC) 252, land grid array (LGA) 256, multi-chip module (MCM) or SIP module 258, quad flat non-leaded package (QFN) 260, quad flat package 262, and embedded wafer level ball grid array (eWLB) 264 are shown disposed on PCB 180. In one embodiment, eWLB 264 is a fan-out wafer level package (Fo-WLP) or a fan-in wafer level package (Fi-WLP).

Depending upon the system requirements, any combination of semiconductor packages, configured with any combination of first and second level packaging styles, as well as other electrical components, can be connected to PCB 180. In some embodiments, electronic device 200 includes a single attached semiconductor package, while other embodiments call for multiple interconnected packages. By combining one or more semiconductor packages over a single substrate, manufacturers can incorporate pre-made components into electronic devices and systems. Because the semiconductor packages include sophisticated functionality, electronic devices can be manufactured using less expensive components and a streamlined manufacturing process. The resulting devices are less likely to fail and are less expensive to manufacture, resulting in a lower cost for consumers.

While one or more embodiments of the present invention have been illustrated in detail, the skilled artisan will appreciate that modifications and adaptations to those embodiments may be made without departing from the scope of the present invention as set forth in the following claims.

What is claimed:

1. A method of making a semiconductor device, comprising:
providing a semiconductor substrate;
forming an integrated passive device (IPD) structure over the semiconductor substrate;
disposing the semiconductor substrate and IPD structure over a glass substrate; and
disposing the semiconductor substrate, IPD structure, and glass substrate over a printed circuit board (PCB).

2. The method of claim 1, further including:
forming a recess in the PCB; and
disposing the glass substrate in the recess.

3. The method of claim 1, further including forming a bond wire between the IPD structure and PCB.

4. The method of claim 1, further including forming a solder bump between the IPD structure and PCB.

5. The method of claim 1, further including backgrinding the semiconductor substrate prior to disposing the semiconductor substrate and IPD structure over the glass substrate.

6. The method of claim 1, further including forming a semiconductor package with the PCB.

7. A method of making a semiconductor device, comprising:
providing a first substrate;
forming an integrated passive device (IPD) structure over the first substrate; and
disposing the first substrate and IPD structure over a glass substrate.

8. The method of claim 7, further including disposing the first substrate, IPD structure, and glass substrate over a second substrate.

9. The method of claim 8, further including:
forming a recess in the second substrate; and
disposing the glass substrate in the recess.

10. The method of claim 8, further including forming a bond wire between the IPD structure and second substrate.

11. The method of claim 8, further including forming a solder bump between the IPD structure and second substrate.

12. The method of claim 8, further including forming a semiconductor package with the second substrate.

13. The method of claim 7, further including backgrinding the first substrate prior to disposing the first substrate and IPD structure over the glass substrate.

14. A semiconductor device, comprising:
a semiconductor substrate;
an integrated passive device (IPD) structure formed over the semiconductor substrate;
a glass substrate attached to the semiconductor substrate opposite the IPD structure; and
a printed circuit board (PCB) with the glass substrate disposed over the PCB.

15. The semiconductor device of claim 14, further including a recess formed in the PCB, wherein the glass substrate is disposed in the recess.

16. The semiconductor device of claim 14, further including a bond wire formed between the IPD structure and PCB.

17. The semiconductor device of claim 14, further including a solder bump disposed between the IPD structure and PCB.

18. The semiconductor device of claim 14, further including a semiconductor die disposed over the PCB.

19. The semiconductor device of claim 14, further including a semiconductor package formed to include the PCB.

20. A semiconductor device, comprising:
a first substrate;
an integrated passive device (IPD) structure formed over the first substrate; and
a glass substrate disposed over the first substrate opposite the IPD structure.

21. The semiconductor device of claim 20, further including a second substrate, wherein the first substrate, IPD structure, and glass substrate are disposed over the second substrate.

22. The semiconductor device of claim 21, further including a recess formed in the second substrate, wherein the glass substrate is disposed in the recess.

23. The semiconductor device of claim 21, further including a bond wire formed between the IPD structure and second substrate.

24. The semiconductor device of claim 21, further including a solder bump disposed between the IPD structure and second substrate.

25. The semiconductor device of claim 21, further including a semiconductor package formed with the second substrate.
